(19) United States
(12) Patent Application Publication
(10) Pub. No.: US 2024/0290885 A1
(43) Pub. Date: Aug. 29, 2024

(54) ENHANCED MOBILITY IN SEMICONDUCTOR DEVICES

(71) Applicant: Applied Materials, Inc., Santa Clara, CA (US)

(72) Inventors: Sai Hooi Yeong, Cupertino, CA (US); Benjamin Colombeau, San Jose, CA (US); Balasubramanian Pranatharthiharan, San Jose, CA (US); El Mehdi Bazizi, San Jose, CA (US); Hui Zhao, Saratoga, CA (US); Ashish Pal, San Ramon, CA (US)

(73) Assignee: Applied Materials, Inc., Santa Clara, CA (US)

(21) Appl. No.: 18/441,886

(22) Filed: Feb. 14, 2024

Related U.S. Application Data
(60) Provisional application No. 63/504,689, filed on May 26, 2023.
(60) Provisional application No. 63/487,501, filed on Feb. 28, 2023.

(51) Int. Cl. H01L 29/78; H01L 21/762; H01L 21/768; H01L 29/06; H01L 29/423; H01L 29/66; H01L 29/775; H01L 29/786

(52) U.S. Cl. CPC H01L 29/7846; H01L 21/76224; H01L 21/76831; H01L 29/0673; H01L 29/42392; H01L 29/66439; H01L 29/775; H01L 29/78696

(57) ABSTRACT

The present technology includes semiconductor devices with improved stress in a channel region. The semiconductor device includes a substrate, a source region, a drain region, a channel region that includes at least one channel located between the source and the drain. Devices include a first gate region having a first self-aligned single diffusion break in a n-MOS region, and a second gate region includes having a self-aligned single diffusion break in a p-MOS region. The second self-aligned single diffusion break also contains a liner and a compressive stressed material, where the stressed metal fill exhibits a compressive stress of about 350 MPa or greater.

### CROSS-REFERENCE TO RELATED APPLICATION

This application claims the benefit of U.S. Provisional No. 63/504,689 filed on May 26, 2023, entitled “ENHANCED MOBILITY IN SEMICONDUCTOR DEVICES,” and U.S. Provisional No. 63/487,501 filed on Feb. 28, 2023, entitled “STRESS INCORPORATION IN SEMICONDUCTOR DEVICES,” the entire contents of which are incorporated herein by reference.

### TECHNICAL FIELD

The present technology relates to methods for semiconductor processing. More specifically, the present technology relates to methods for incorporating increased stress in doped regions of semiconductor devices.

### BACKGROUND

Integrated circuits have advanced into complex devices that can include millions of transistors, capacitors, and resistors on a single chip. In the course of integrated circuit evolution, functional density (i.e., the number of interconnected devices per chip area) has generally increased while geometry size has decreased. Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate field-effect transistors (FETs) in which current flows through a semiconducting channel between a source and a drain, in response to a voltage applied to a control gate.

Integrated circuits are made possible by processes which produce intricately patterned material layers on substrate surfaces. Producing patterned material on a substrate requires controlled methods for forming and removing material. As device sizes continue to reduce, film characteristics may lead to larger impacts on device performance. As devices shrink and more complex patterning schemes are utilized in the industry, deposition of thin films becomes a challenge. In addition, as material thicknesses continue to reduce, as-deposited characteristics of the films may have a greater impact on device performance. These challenges include depositing void free and stressed films.

Thus, there is a need for high-quality devices and structures having improved mobility, and methods of making such devices. These and other needs are addressed by the present technology.

### BRIEF SUMMARY OF THE INVENTION

The present technology is generally directed to semiconductor devices, systems, and methods of forming such devices and systems. Semiconductor devices include a substrate, a source region, a drain region, and a channel region having at least one channel located between the source and the drain. Devices also include a first gate region having a first self-aligned single diffusion break in a n-MOS region, and a second gate region having a second self-aligned single diffusion break in an p-MOS region. Devices include where the second self-aligned single diffusion break includes a compressive stressed fill material characterized by a compressive stress of greater than or about 350 MPa. Devices include where the first self-aligned single diffusion break includes a first liner and a first fill material.

In embodiments, devices include where the first fill material is a neutral stressed material or a tensile stressed material. In more embodiments, the first fill material, the compressive stressed fill material, or both the first fill material and the compressive stressed fill material include a dielectric fill material. Moreover, in embodiments, devices include where the first fill material and the compressive stressed fill material include dielectric fill materials, where the first fill material is different from the second fill material. In embodiments, the dielectric fill material includes silicon nitride, silicon oxynitride, silicon dioxide, or a combination thereof. Furthermore, in embodiments, the second self-aligned single diffusion break includes a second liner. In yet more embodiments, the first liner, the second liner, or both the first liner and the second liner include a dielectric liner material. In embodiments, the dielectric liner material includes silicon nitride, silicon oxynitride, silicon dioxide, or a combination thereof. Additionally or alternatively, in embodiments, the dielectric liner material of the first liner has an etch rate that is different than an etch rate of the first fill material. In further embodiments, the dielectric liner material of the second material is selected from a same material or a different material from the compressive stressed fill material. In embodiments, the second liner includes silicon nitride, silicon dioxide, or a combination thereof, and the compressive stressed fill material includes silicon dioxide, silicon nitride, or a combination thereof. Moreover, in embodiments, the first fill material includes silicon nitride, silicon dioxide, or a combination thereof, where the second fill material is different than the first fill material. In yet another embodiment, the semiconductor devices may be a nanosheet field-effect transistor or a complementary field-effect transistor, and/or a gate-all-around complementary metal-oxide semiconductor.

The present technology is also generally directed to semiconductor processing systems. Systems include a first processing chamber, a second processing chamber, a third processing chamber, and a system controller. Systems include where the controller is configured to pattern a substrate in the first processing chamber. Systems include where the controller is configured to etch a first shallow trench isolation in a first gate region and a second shallow trench isolation in a second gate region, where the first gate region is a n-MOS region and the second gate region is a p-MOS region, in the second processing chamber. Systems include where the controller is configured to line the first shallow trench isolation and the second shallow trench isolation with a dielectric liner, fill the first shallow trench isolation and second shallow trench isolation with a neutral stressed material or a tensile stressed material, remove the neutral stressed material or tensile stressed material from the first shallow trench isolation, and fill the first shallow trench isolation with a compressive stressed material, in the third processing chamber.

The present technology is also generally directed to a method of forming semiconductor devices. Methods include etching a first shallow trench isolation in a first gate region and a second shallow trench isolation in a second gate region, where the first gate region is a n-MOS region and the second gate region is a p-MOS region. In methods, the semiconductor device includes a substrate, a source region, a drain region, and a channel region containing at least one channel located between the source and the drain. Methods include lining the first shallow trench isolation and the second shallow trench isolation with a liner. Methods include filling the lined first shallow trench isolation and second shallow trench isolation with a neutral stressed or tensile stressed material. Methods include etching the neutral stressed or tensile stressed material from the gate region. Methods include filling the etched second shallow trench isolation with a compressive stressed material.

In embodiments, methods include where no polishing step is conducted between filling the lined first shallow trench isolation with the neutral stressed or tensile stressed material and filling the etched second shallow trench isolation with a compressive stressed material. In more embodiments, methods include where etching the neutral stressed or tensile stressed material is a wet etching or a dry etching process. In yet further embodiments, methods include where the liner includes a dielectric liner material having an etch rate that is different than an etch rate of the neutral stressed material or tensile stressed material. In embodiments, methods include where the liner includes silicon nitride, silicon oxynitride, silicon dioxide, or a combination thereof. In embodiments, the compressive stressed material includes silicon nitride, and the neutral stressed or tensile stressed material includes silicon nitride or silicon dioxide.

Such technology may provide numerous benefits over conventional techniques. For example, embodiments of the present technology produce desired levels of stress in the channel region of a semiconductor transistor without changing the composition of the adjacent source and drain regions. In addition, the present technology originates the channel region stress from an existing diffusion break, thus allowing more compact devices to be formed with improved stress. The present technology may therefore provide for improved stress without requiring additional channels or diffusion breaks having increased size. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing chamber according to some embodiments of the present technology.

FIG. 2 shows selected operations in a formation method according to some embodiments of the present technology.

FIGS. 3A-3H show cross-sectional views of exemplary semiconductor structures according to some embodiments of the present technology.

FIG. 4 shows a cross-sectional view of exemplary semiconductor structures according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

The present technology includes electronic devices and methods of forming electronic devices having one or more self-aligned single diffusion breaks. Such electronic devices may include a semiconductor transistor, such as n-channel and p-channel MOSFETs, FinFETs, gate-all-around FETs, and nanosheet FETs, among other types of transistors, as well as products having such channel regions. In conventional process methods, the stress level in the transistor channel may be controlled by altering the composition of the semiconductor materials in the channel, as well as the compositions of the materials in the adjacent source and drain regions. In many instances, the changes to the compositions of these doped regions of the transistor to give the channel region a desired amount of stress can lead to less desirable transistor performance in other respects, such as a lower thermal budget and/or an increased resistance at the interface between the contact and the doped region. Controlling channel region stress by altering the composition of the doped regions also limits the types of materials that can be used in the doped regions. For example, modern PMOS transistors often use a doped silicon-germanium (SiGe) semiconductor in the doped regions of the transistor. When the Ge-to-Si ratio gets too high, lattice mismatches create faults in the material that can reduce the channel region stress below an acceptable level.

Another conventional method for increasing the stress in a channel region of a transistor is depositing a stressed conductive material in the contact trench above the channel region. The stress from the conductive material is transmitted down to impart the desired stress in the doped material of the channel region. These conventional methods require careful selection and deposition of the conductive material in the contact trench to meet the stress requirements as well as the electrical conductivity, chemical reactivity, hermeticity, thermal budget, and other requirements for the material. In many instances, there must be a compromise in selecting a conductive material with less-than-ideal characteristics in some respects in order to satisfy the stress requirement. The changes in the deposition method or composition of the stressed material to create additional stress can diminish the performance of the material in other respects, such as electrical conductivity.

Nonetheless, conventional methods have proven increasingly ineffective with the rise of increasingly complicated gate and channel surface orientations. Namely, the gate orientation of multi-channel semiconducting nanostructures, such as gate-all-around, complementary FET, nanosheet, and nanowire orientations, as examples only, hinder the effectiveness of conventional stress applications. As one example, conventional methods for increasing stress may apply adequate stress at an upper and/or lower gate but fails to provide the necessary stress on gates disposed therebetween. Furthermore, due at least in part to poor stress consistency in addition to unfavorable surface orientations, multi-channel semiconducting nanostructures also exhibit unfavorable hole and/or electron mobility. Such hole mobility deficiencies are particularly apparent in comparison to traditional gate and favored channel orientations, such as fin field-effect transistors (FinFET).

Efforts to improve channel strain in multi-channel semiconducting nanostructures in particular include source and drain regions formed via an epitaxial growth process. However, due to the complex geometries and surface orientations, epitaxial merging consistently suffers from dislocations during and after formation. Such dislocations can pull the epitaxially grown material away from the gates, as well as create dislocation seams, leading to a relaxation in the channel stress over time. This has proved particularly problematic for hole mobility, such as in p-type metal oxide semiconductor (PMOS) regions. Methods have sought to improve epitaxial merge defects as a method to impart consistent channel stress. However, none of the existing methods have proven sufficient to provide consistent stress, improve electron and hole mobility, or a combination thereof.

The present technology overcomes these and other challenges by providing consistently stressed channels having improved hole and/or electron mobility. By utilizing self-aligned single diffusion breaks having a liner filled with one or more fill materials based upon the self-aligned single diffusion break's location in a p-MOS or n-MOS region, stressed channel regions may be provided with desired stress. In addition, by utilizing the unique combination of a liner and a tailored fill material, formation of self-aligned diffusion breaks in both p-MOS and n-MOS regions may be achieved without requiring intermediate polishing operations. In embodiments of the present technology, the stresses may originate with the deposition of a stressed material in one or more self-aligned single diffusion breaks that are adjacent to one or more doped regions of the transistor, such as a channel region. The stressed material may initially impart stress to the one or more self-aligned single diffusion breaks, which in turn may transmit a portion of the stress to the channel region of the transistor.

Although the remaining disclosure will routinely identify specific metal-oxide-semiconductor field-effect transistors (MOSFET), complementary metal-oxide semiconductors (CMOS), and components thereof, it will be readily understood that the device and methods are equally applicable to other field-effect transistors, orientations thereof, as processes for forming such devices. Accordingly, the technology should not be considered to be so limited as for use with these specific devices or methods alone. The disclosure will discuss one possible semiconductor device that may include one or more components, utilizing one or more self-aligned single diffusion breaks according to embodiments of the present technology before additional variations and adjustments to this apparatus according to embodiments of the present technology are described.

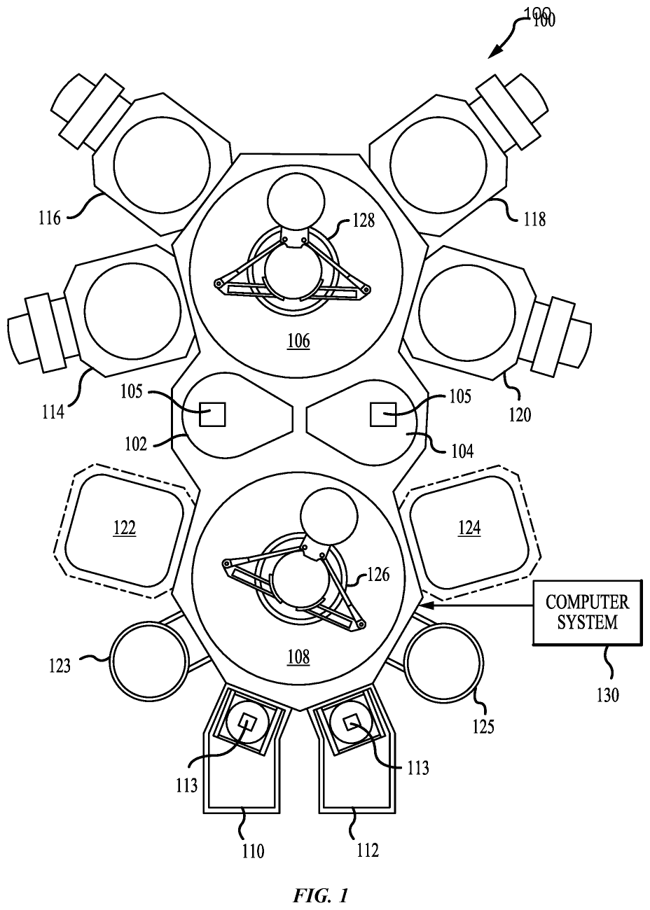

FIG. 1 illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

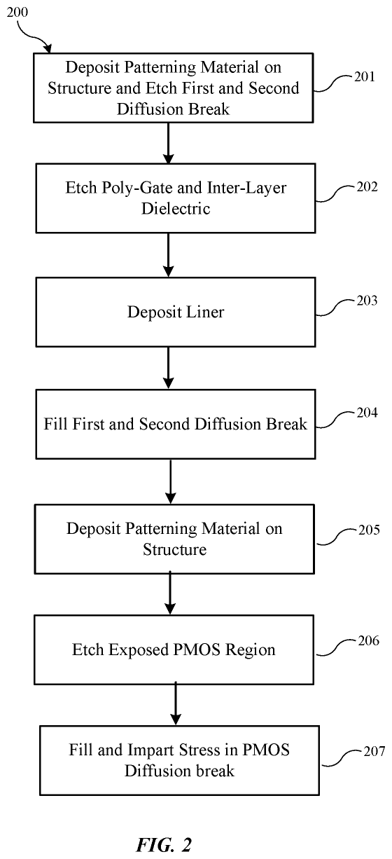

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

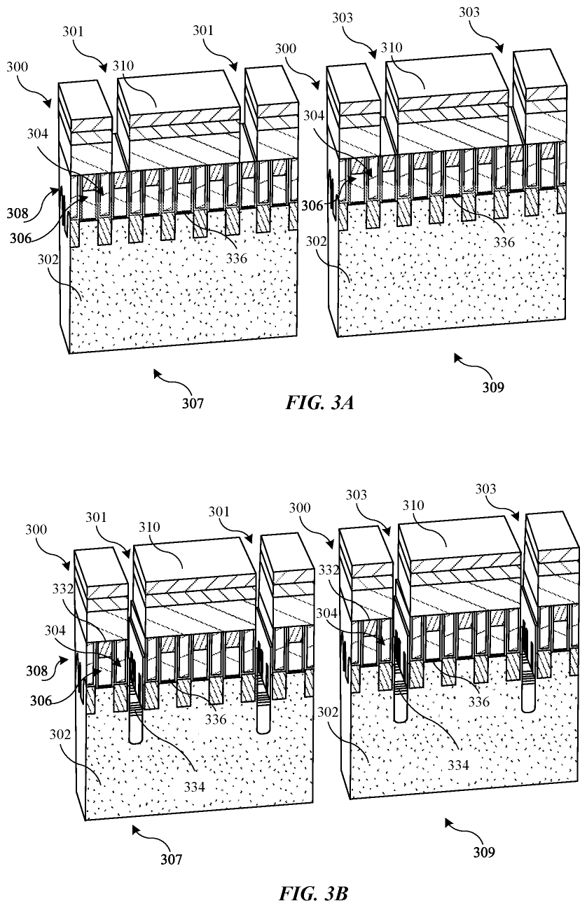

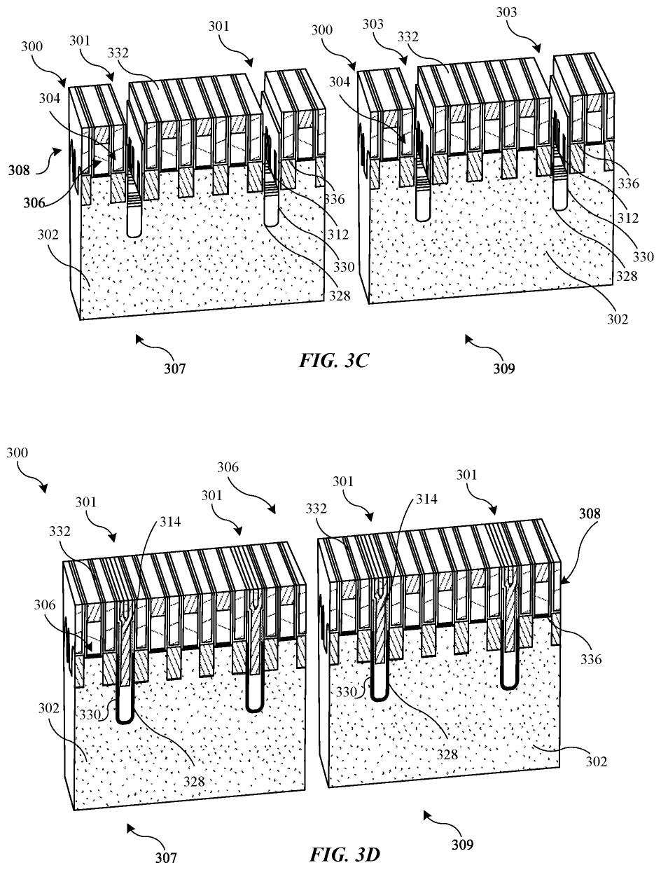

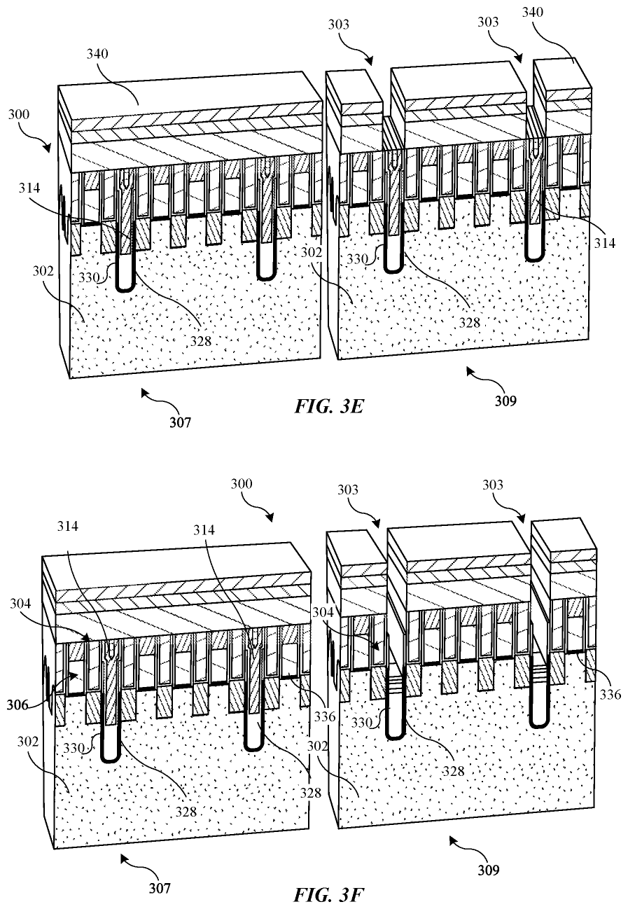

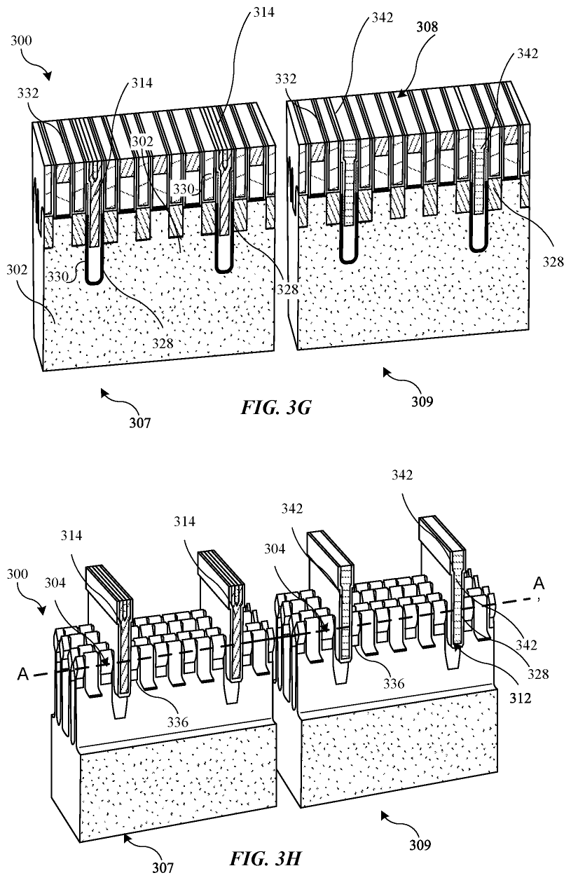

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region 120 described above. Method 200 describes operations shown schematically in FIGS. 3A-3H, the illustrations of which will be described in conjunction with the operations of method 200. It is to be understood that FIG. 3A-3H illustrate only partial schematic views, and a semiconductor substrate may include further components as illustrated in the figures, as well as alternative components, of any size or configuration that may still benefit from aspects of the present technology. For instance, FIGS. 3A-3H illustrate a first region 307 adjacent to a second region 309. The regions 307, 309 are illustrated with a gap therebetween in order to indicate that the first region 307 may be directly adjacent to second region 309, or may be spaced apart from second region 309 (e.g. having one or more intermediate regions therebetween).

Method 200 may or may not involve optional operations to develop the semiconductor structure to a particular fabrication operation. It is to be understood that method 200 may be performed on any number of semiconductor structures 300 or substrates 302, as illustrated in FIG. 3A-3H, including exemplary structures on which a selective deposition material may be formed. As illustrated in FIG. 3A substrate 302 may have a number of layers of material deposited overlying the substrate. Substrate 302 may be any number of materials, such as a base wafer or substrate made of silicon or silicon-containing materials, germanium, other substrate materials, as well as one or more materials that may be formed overlying the substrate during semiconductor processing.

Structure 300 may illustrate a partial view of a substrate, which in embodiments may be used in n-channel and p-channel MOSFETs, FinFETs, gate-all-around FETs, complementary metal-oxide semiconductors, and nanosheet FETs, among other types of semiconductor transistor structures. The layers of material may be produced by any number of methods, including chemical vapor deposition (CVD), physical vapor deposition (PVD), atomic layer deposition (ALD), thermally enhanced chemical vapor deposition (TECVD), plasma-enhanced chemical vapor deposition (PECVD), plasma enhanced atomic layer deposition (PEALD), or any other formation technique. In embodiments, plasma-enhanced chemical vapor deposition may be performed in a processing chamber, such as processing chamber 100 described previously. Substrate layers can include silicon oxide and silicon nitride, silicon oxide and silicon, silicon nitride and silicon, silicon and doped silicon, or any number of other materials.

As illustrated in FIG. 3A, structure 300 is provided that includes a substrate 302 that has already undergone source/drain 304 formation. In embodiments, source/drain 304 formation may include epitaxial growth of a doped silicon material such as a silicon-germanium material. Although, it should be understood that the source/drain region 304 may be formed from any suitable deposition and patterning process, as the present technology does not require stringent source/drain 304 formation (e.g., attempts to cure epitaxial growth defects) to maintain hole or electron mobility. In addition, structure 300 contains a plurality of gate regions 306 and interlayer dielectric/dummy gate region 308, which may be formed as known in the art and discussed above.

In embodiments, the structure 300 may be a bulk semiconductor substrate. As used herein, the term “bulk semiconductor substrate” refers to a substrate in which the entirety of the substrate is comprised of a semiconductor material. The bulk semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 300 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. As discussed above, in embodiments, the present technology may provide improved mobility in both p and n-type semiconductors. However, in embodiments, p-type semiconductors may experience further improved hole mobility.

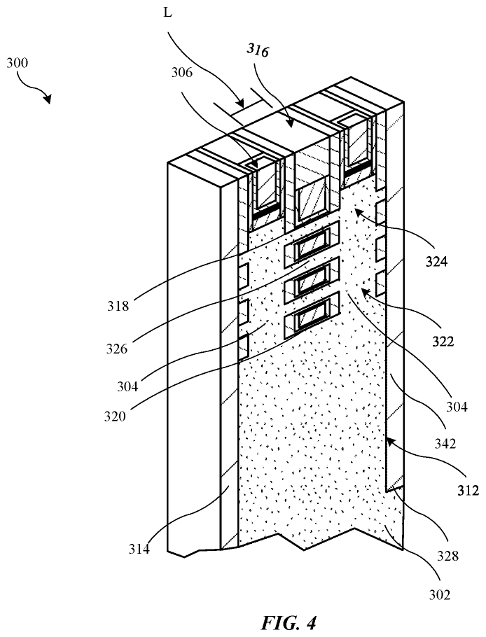

Nonetheless, at operation 201, method 200 may include patterning one or more mask layers 310 deposited on the substrate 302 on the upper surface of the source/drain regions 304 and a portion of gate regions 306. For instance, in embodiments, a substrate 302 may be loaded into load lock 110,112, and transferred to a process chamber (such as process chamber 114) via robots 126, 128, where a mask deposition process is conducted. Namely, as illustrated, one or more mask layers 310 are patterned above five of the seven illustrated gate regions 306, leaving two gate regions 306 exposed. However, as will be discussed in greater detail below, it should be understood that the patterned mask layers 310 may be disposed above one or more gates regions 306 or spaced apart at intervals as necessary to provide the necessary stress on channel regions 316 (shown more clearly in FIG. 4).

As illustrated in FIG. 3B, at operation 202, method 200 may include etching the structure 300. In embodiments, such an operation may include transferring substrate 302 to a second process chamber 116, configured for etching processes. For instance, in one embodiment, one or more of inductively coupled plasma (ICP) etching, reactive ion etching (RIE), or capacitively coupled plasma (CCP) etching is used to form shallow trench isolation or via 312. Furthermore, as the mask layers 310 are aligned with gate regions 306, the shallow trench isolations 312 may be formed in and self-aligned with a gate region, and thus considered to be self-aligned shallow trench isolations or self-aligned single diffusion breaks. Moreover, while other configurations may be utilized, in embodiments, a first gate region 307 which may be a n-MOS region contains a first self-aligned diffusion break 301 (which may be a pair of breaks 301 in embodiments) and second gate region 309 may be a p-MOS region contains a second self-aligned diffusion break 303 (or pair of breaks 303 in embodiments), or vice-a-versa. Although, it should be clear that the semiconductor substrate may include more than two diffusion breaks, or more than two pairs of diffusion breaks) based upon the size of the structure. In addition, while the self-aligned diffusion breaks are illustrated as being in distinct regions, it should be clear that other arrangements, including side-by-side within the same region are contemplated, as known in the art, as the methods provided by the present technology allow the formation of different materials in adjacent or spaced apart self-aligned diffusion breaks.

After etching the structure 300 at operation 202, method 200 may include an optional passivation and/or oxidation treatment after removal of mask layers(s) 310, as illustrated in FIG. 3C. Nonetheless, the etched substrate 302 may be transferred to a third process chamber 118 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. For instance, in such a process chamber 118, a liner 328 may be formed in the first self-aligned diffusion break 301 and in the second self-aligned diffusion break 303, at operation 203 along exterior perimeter 330 (or an exterior sidewall) of each respective self-aligned diffusion break 301, 303, as shown in FIG. 3C.

In embodiments, the liner 328 may be formed from any dielectric material having a different etch rate than second fill material, which will be discussed in greater detail below, as known in the art. For instance, exemplary liner materials include silicon oxide, silicon nitride, silicon oxynitride, silicon oxycarbonitride, silicon carbonitride, silicon oxycarbide, silicon dioxide, aluminum oxide, and carbon-containing organic materials, among other types of dielectric materials, and combinations thereof. Nonetheless, in embodiments, the liner may be a dielectric material, such as a silicon nitride, a silicon oxynitride, silicon dioxide, or other similar materials. In embodiments, the liner 328 may be referred to as a first liner (e.g. the portion of the liner disposed in the first self-aligned diffusion break) and a second liner (e.g., the portion of the liner disposed in the second self-aligned diffusion break), as the liner 328 may not be continuous between respective diffusion breaks. However, in embodiments, the first liner and second liner may be formed from the same material or different materials, and may be formed from any one or more of the materials discussed above.

In embodiments, the liner 328 may be characterized by thickness of greater than or about 0.5 nm, such as greater than or about 1 nm, greater than or about 1.5 nm, greater than or about 2 nm, greater than or about 2.5 nm, greater than or about 3 nm, greater than or about 3.5 nm, greater than or about 4 nm, greater than or about 4.5 nm, greater than or about 5 nm, or more. Further, the liner 328 may be characterized by a thickness of less than or about 8 nm, such as less than or about 7 nm, less than or about 6 nm, less than or about 5 nm, less than or about 4.5 nm, or less, or any ranges or values therebetween. By utilizing a liner thickness within the above ranges, breakdown voltage degradation can be avoided while imparting significant stress to the channel region. Namely, with liner thickness, less stress is transferred to the channel region from the respective fill material. Thus, it is important to balance a thick enough liner to prevent breakdown voltage degradation without losing desired stress.

After formation of the liner at operation 203 in the first self-aligned diffusion break 301 and second self-aligned diffusion break 303, the method 200 may include a filling operation 204, where a first fill material 314 is provided in both the first self-aligned diffusion break and the second self-aligned diffusion break. The filling operation 204 may occur in the same deposition chamber 218, or the substrate 302 may be transferred to a further process chamber. In embodiments, the filling operation of first fill material 314 may be conducted via chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. In embodiments, the first fill material 314 may be filled via plasma enhanced atomic layer deposition.

In embodiments, the fill may occur with a stressed material, such as a tensile stressed material, or may include an unstressed material (e.g., a neutral stressed material). Moreover, a tensile stressed material may be filled as an unstressed material, and then configured to provide the necessary stress. For instance, when an unstressed material is used but overall tensile stress is desired, an additional treatment may be utilized to impart the necessary stress to the filled material. In embodiments, the first fill material may include a dielectric material such as a silicon oxide, silicon nitride, silicon oxynitride, silicon oxycarbonitride, silicon carbonitride, silicon oxycarbide, silicon dioxide, aluminum oxide, and carbon-containing organic materials, among other types of dielectric materials, and combinations thereof. In embodiments, the first fill material may be silicon dioxide, silicon nitride, silicon oxynitride, or a combination thereof.

Moreover, as discussed above, the first fill material may be a neutral stressed material or a tensile stressed material. Thus, in embodiments, a tensile stressed material may be utilized (or tensile stress may be induced in the stressed dielectric material). For instance, high oxygen deposition environments, or UV curing may be utilized, as examples only may be utilized in conjunction with any one or more of the above listed first fill materials. Nonetheless, the present technology has found that the deposition of a tensile stressed dielectric material in a single self-aligned diffusion break in a n-MOS region can further improve electron mobility and n-MOS current drive without detrimentally effecting the hole mobility and p-MOS current drive properties discussed herein.

In embodiments, the first fill may be characterized by a neutral stress of approximately 0 MPa (e.g. a stress of about −10 to about 10 MPa, such as from about −7.5 MPa to about 7.5 MPa, such as from about −5 MPa to about 5 MPa, such as from about −2.5 MPa to about 2.5 MPa, such as from about −1 MPa to about 1 MPa, or any ranges or values therebetween), or a tensile stress of greater than or about 250 MPa, such as greater than or about 350 MPa, such as greater than or about 400 MPa, greater than or 500 MPa, greater than or about 600 MPa, greater than or about 700 MPa, greater than or about 800 MPa, greater than or about 900 MPa, greater than or about 1 GPa, or more, or any ranges or values therebetween. For the purposes of this disclosure, a higher-stress material is characterized by an absolute value of stress, either positive or negative, that is greater than the absolute value of a lower-stress material. The convention used here is that positive stress is characterized as tensile stress, negative stress is characterized as compressive stress, and no stress (i.e., 0 GPa) is characterized as neutral stress. Positive (i.e., tensile) stress may characterized by an outward pushing force that may be created by the expansion of a material. Negative (i.e., compressive) stress may be characterized by an inward pulling force that may be created by the contraction of the material. Thus, a “compressive stressed” value as used herein may refer to a negative of the absolute value (e.g., a compressive stress of 250 MPa could also be read as −250 MPa), and a “tensile stressed” value as used herein may refer to a positive of the absolute value (e.g., a tensile stress of 250 MPa refers to 250 MPa).

Thus, in addition to the improvements discussed herein in regards to improve hole mobility in a p-MOS region, the increased stress in the channel region is thought to increase the mobility of charge carriers in the channel, which increases the drive current through the n-MOS channel region. In embodiments, the increased stress created in the channel region by embodiments of the present technology may increase the drive current through a transistor channel by greater than or about 1%, such as greater than or about 5%, greater than or about 10%, greater than or about 15%, greater than or about 20%, greater than or about 25%, greater than or about 30%, greater than or about 35%, greater than or about 40%, greater than or about 45%, greater than or about 50%, greater than or about 55%, or greater, or any ranges or values therebetween. An increase in drive current and hole mobility through the channel region may increase transistor performance in a number of respects including, but not limited to, increased switching speed and/or reduced power consumption.

Nonetheless, in embodiments, the first fill material may be selected to have a different etch rate than an etch rate of the liner 328. For instance, in embodiments, both the liner 328 and the first fill material may be dielectric materials, and may both be independently selected from silicon oxide, silicon nitride, silicon oxynitride, silicon oxycarbonitride, silicon carbonitride, silicon oxycarbide, silicon dioxide, aluminum oxide, and carbon-containing organic materials, among other types of dielectric materials, and combinations thereof, such as, silicon nitride, silicon oxide, silicon oxynitride, in embodiments. However, in embodiments, the first fill material is selected to be a different material than the liner material. Nonetheless, as illustrated, liner 328 forms a barrier between the first fill material 314 and the neighboring source-drain regions 304.

In embodiments, the first fill material can be filled into the lined 328 self-aligned diffusion breaks 301, 303 using void free and stressed deposition processes as known in the art. For instance, chemical vapor deposition (CVD) and ALD (including PEALD) deposition of these materials can include using any appropriate precursors. For example, CVD and ALD may be suitable for deposition, utilizing any appropriate precursor of the first and/or second fill materials, as well as other fill processes as known in the art and discussed above.

Nonetheless, in embodiments, the deposition of the first fill material 314 may occur at a temperature of greater than or about 150° C., such as greater than or about 200° C., greater than or about 250° C., greater than or about 300° C., greater than or about 350° C., greater than or about 400° C., or greater. Additionally, deposition of the first fill material may be performed at a temperature of less than or about 500° C., such as less than or about 450° C., or less, or any ranges or values therebetween.

After the first fill operation 204, a second patterning operation 205 is conducted. As illustrated in FIG. 3E, at operation 205, one or more mask layers 340 are patterned/deposited on the substrate 302 on the upper surface of the source/drain regions 304 and a portion of gate regions 306. However, unlike operation 201, as illustrated in FIG. 3E, the one or more mask layers 340 (which may be formed from the same or different materials from mask layers 310) are patterned above five of the seven illustrated gate regions 306 as well as the first self-aligned diffusion break 301, leaving the second self-aligned diffusion break 305 (e.g., in a p-MOS region), exposed. In embodiments, the mask 340 may leave more than one self-aligned diffusion break exposed, such as a portion of, or each, self-aligned diffusion break in a p-MOS region while covering a portion of, or each, self-aligned diffusion break in a n-MOS region.

As illustrated in FIG. 3F, at operation 206, method 200 may include etching the structure 300 having the first fill material disposed in the first and second self-aligned diffusion breaks 301, 303. In embodiments, such an operation may include transferring substrate 302 back to a second process chamber 116, or to a further process chamber, configured for etching processes. For instance, in one embodiment, one or more of inductively coupled plasma (ICP) etching, reactive ion etching (RIE), or capacitively coupled plasma (CCP) etching is used to remove the first fill material 314 from the second self-aligned diffusion break. In embodiments, the etching process may be a wet or dry etching process, such as with hydrofluoric acid, phosphoric acid, or the like, as well as other etchants known in the art or based upon the first fill material and liner material utilized.

Namely, as discussed above, in embodiments, the first fill material and the liner may be selected to have different etch rates. In such a manner, the first fill material may be effectively removed from the lined second-self aligned diffusion break without damaging the surrounding structure. For instance, as the first fill material 314 may be selectively etched, the liner 328 may remain in place, protecting the side and bottom surface of the second self-aligned diffusion break. Moreover, such a process also allows for the deposition and fill of different materials into a first self-aligned diffusion break and a second self-aligned diffusion break without an intermediate polishing operation (e.g. between the first material fill and the second material fill, discussed below). Thus, the present technology provides a structure that exhibits reduced surface losses, improving the electrical properties of the semiconductor structure, as, in embodiments, the semiconductor structure is not subjected to an intermediate polishing operation.

After removing the first fill material 314 from the second self-aligned diffusion break at operation 206, the second self-aligned diffusion break 303 (e.g. disposed in a p-MOS region) may be filled with a compressive stressed material 342. The compressive stressed material may be filled into the lined second self-aligned diffusion break 303 utilizing atomic layer deposition, plasma-enhanced atomic layer deposition, chemical vapor deposition, plasma-enhanced chemical vapor deposition, among other types of deposition methods as discussed above. In embodiments, the second fill material 342 may be a dielectric material, such as any one or more of the dielectric materials discussed above. However, unlike the first fill material 314, there is no requirement that the second fill material (compressive stressed material) 342 be different than liner 328. Thus, in embodiments, the compressive stressed material may include a dielectric material such as a silicon oxide, silicon nitride, silicon oxynitride, silicon oxycarbonitride, silicon carbonitride, silicon oxycarbide, silicon dioxide, aluminum oxide, and carbon-containing organic materials, among other types of dielectric materials, and combinations thereof, which may be the same material or a different material than the liner 328 material. In embodiments, the compressive stressed material may be silicon nitride, silicon oxynitride, silicon dioxide, or a combination thereof. In embodiments, the compressive stressed material may be selected to be a different material than the first fill material.

Nonetheless, in order to deposit the compressive stressed material, the deposition of the compressive stressed material may occur by utilizing increased RF power, higher deposition temperatures, higher kinetic energy plasma levels, or combinations thereof. Thus, in embodiments, the deposition process may occur with deposition temperatures of greater than or about 150° C., such as greater than or about 200° C., such as greater than or about 250° C., such as greater than or about 300° C., such as greater than or about 350° C., such as greater than or about 400° C., such as greater than or about 450° C., such as greater than or about 500° C., such as greater than or about 550° C., such as greater than or about 600° C., such as up to about 700° C., such as less than or about 650° C., or any ranges or values therebetween.

In embodiments, the compressive stressed material may be characterized by a stress of greater than or about 250 MPa, such as greater than or about 350 MPa, such as greater than or about 500 MPa, such as greater than or about 1 GPa, such as greater than or about 1.5 GPa, such as greater than or about 2 GPa, such as greater than or about 2.25 GPa, such as greater than or about 2.5 GPa, such as greater than or about 2.75 GPa, such as greater than or about 3 GPa, or any ranges or values therebetween.

However, it should be understood that, in embodiments, the second self-aligned diffusion break 303 is filled with a compressive stressed material, and/or the first self-aligned diffusion break 301 is filled with a neutral or tensile stressed material such that greater than or about 90 vol. % of the volume defined by the respective self-aligned diffusion break is occupied with the respective material, such as greater than or about 92 vol. %, greater than or about 94 vol. %, greater than or about 96 vol. %, greater than or about 98 vol. %, greater than or about 99 vol. %, or more, or any ranges or values therebetween. In embodiments, the volume defined by the self-aligned diffusion break may be completely occupied with the respective material and no void or seam may be present. Namely, the present technology has found that even small voids in the self-aligned diffusion break can result in dramatic decreases in channel stress. For instance, voids or seams characterized by a size of less than or about 3 nm or less, such as less than or about 2 nm, or less than about 1 nm may result in a decrease in average channel stress of greater than 60%.

Thus, in embodiments, to obtain the high vol. % and decrease voids and seams, the filling steps 204 and/or 207 may include only forming a thin layer of the respective fill material, etching back part of the filled material, and then filling another thin layer of the respective fill material, repeating in a cyclic in-situ manner until the self-aligned diffusion break filling is complete. Such a process may be particularly useful in high aspect ratio diffusion breaks, as the cyclic process may avoid pinch off, and allow for lower volume of voids and seams, and higher occupied volume of the stressed dielectric material.

As noted above, the present technology has found that even thin layers of the compressive stressed material and/or tensile stressed material (when utilized) may be effective for imparting stress when utilized in the respective self-aligned diffusion break. Thus, the above thicknesses may represent the full width of the self-aligned diffusion break. In such instances, the respective self-aligned diffusion break may define a channel length L, defined as the distance between the source and drain regions as illustrated in FIG. 4. Channel length L may be characterized by a length of less than or about 35 nm, such as less than or about 30 nm, less than or about 25 nm, less than or about 20 nm, or less, or any ranges or values therebetween. In embodiments, the self-aligned diffusion break may be considered to be characterized by a high aspect ratio due to the small channel length and large diffusion break depth. In addition, in embodiments, only single self-aligned diffusion breaks, and no double diffusion breaks, are utilized in structure 300 while still imparting the necessary stress, thus allowing reduced size while maintaining effectiveness.

Nonetheless, after formation of liner 328, first fill material 314, and second fill material 342, the substrate 302 may be transferred to a fourth process chamber 120, such as a process chamber configured for polishing, including chemical mechanical polishing. Thus, at operation 205, method 200 may include polishing the structure 300, such as chemical mechanical polishing, of the top surface 332 of structure 300 (FIG. 3G). A further view of FIG. 3G is illustrated in FIG. 3H, where the interlayer dielectric 308 and gate regions 306 have been removed for clarity. In addition, FIG. 4 illustrates a cross-sectional view of an exemplary embodiment, such as along line A-A′ of FIG. 3E. FIG. 4 may more clearly show source/drain regions 304, gate regions 306, and channel regions 316. As illustrated, in embodiments, the structure 300 may be a horizontal gate-all-around orientation, having a plurality of horizontally extending channels 326 in channel region 316. For instance, in embodiments, the channels 326 may be generally parallel with a top surface 336 of substrate 302.

Namely, the present technology has surprisingly found that by utilizing a liner 328 around a perimeter 330 of a first and second self-aligned diffusion break 301, 303, and then filling a first self-aligned diffusion break 301 with a tensile stressed or neutral stressed material first fill material 314 and a second self-aligned diffusion break 303 with a compressive stressed material 342, excellent electron and/or hole mobility may be achieved without subjecting the semiconductor structure to surface loss. The same is true even in structures having disfavored channel surface orientation. Moreover, by utilizing the combination of fill materials and liners as discussed herein in the self-aligned diffusion breaks, the present technology may transfer compressive stress from the stressed material, alone or in combination with tensile stress from the first fill material in embodiments, to the neighboring channel regions without suffering from channel stress relaxation exhibited in existing technologies.

For instance, in the present technology, the stress in the one or more channel regions 316 (FIG. 3H, shown more clearly in FIG. 4) increases from a lower-stress, first stress amount prior to incorporation of the fill materials to a higher-stress, second stress amount after formation of the one or more stressed diffusion breaks. In embodiments, the percentage change in the stress of a channel region 316 from the first stress amount to the second stress amount may be greater than or about 0.1%, such as greater than or about 1%, greater than or about 2%, greater than or about 5%, greater than or about 10%, greater than or about 25%, greater than or about 50%, greater than or about 75%, greater than or about 100%, or more, or any ranges or values therebetween. In additional embodiments, the first stress amount in a channel region 316 may be less than or about 10 MPa, such as less than or about 5 MPa, less than or about 1 MPa, or less. In further embodiments, the second stress amount in a channel region 316 may be greater than or about 100 MPa, such as greater than or about 200 MPa, greater than or about 300 MPa, greater than or about 400 MPa, greater than or about 500 MPa, greater than or about 600 MPa, or any ranges or values therebetween.

In addition, in embodiments, the present technology has found that such stress may be evenly distributed throughout the channel region 316. As noted above, previous attempts have utilized stressed materials above and below the channel regions. However, conventional technologies may limit stress improvement to a top side 318 of the channel region 316 and/or a bottom side 320 of the channel region 316. Accordingly, conventional technologies may fail to provide consistent stress throughout the entirety of the channel. Conversely, in embodiments, the present technology may have a first channel stress at a first location 322 in channel region 316 (illustrated as adjacent to bottom 320 of channel region 316 for example only, it should be understood that first location 322 may be at any location within channel region 316), and a second channel stress at a second location 324 in channel region 316. As illustrated, the first location 322 may be spaced apart from second location 424 in a vertical direction for exemplary purposes. However, in embodiments, the regions may be spaced apart horizontally, or both vertically and horizontally. Nonetheless, the first channel stress may vary from the second channel stress by less than or about 30%, such as less than or about 27.5%, less than or about 25%, less than or about 22.5%, less than or about 20%, less than or about 17.5%, less than about 15%, less than about 12.5%, less than or about 10%, or any ranges or values therebetween.

Furthermore, as noted above, the increased stress in the channel region is thought to increase the mobility of charge carriers in the channel, which also may increase the drive current through the channel region. Specifically, the increased stress created in the channel region in embodiments of the present technology may increase the drive current, such as the p-MOS drive current and/or the n-MOS drive current, through a transistor channel by greater than or about 1%, such as greater than or about 5%, greater than or about 10%, greater than or about 15%, greater than or about 20%, greater than or about 25%, greater than or about 30%, greater than or about 35%, greater than or about 40%, greater than or about 45%, greater than or about 50%, greater than or about 55%, or any ranges or values therebetween. In embodiments, the increased stress in the channel region may lead to an even further increase in the hole mobility, such as in an amount of greater than or about 10%, greater than or about 20%, greater than or about 30%, greater than or about 40%, greater than or about 50%, greater than or about 60%, greater than or about 70%, greater than or about 80%, greater than or about 90%, greater than or about 100%, greater than or about 110%, greater than or about 120%, greater than or about 130%, greater than or about 140%, greater than or about 150%, or any ranges or values therebetween. An increase in drive current and hole mobility through the channel region can increase transistor performance in a number of respects including, but not limited to, increased switching speed and/or reduced power consumption. Embodiments of the present technology may accomplish these improvements in semiconductor device performance without constraining the types of materials used in the devices that may create new processing problems or compromise device performance in other respects.

In embodiments the self-aligned diffusion break may define a channel length L, defined as the distance between the source and drain regions as illustrated in FIG. 4. Channel length L may be characterized by a length of less than or about 35 nm, such as less than or about 30 nm, less than or about 25 nm, less than or about 20 nm, or less, or any ranges or values therebetween. Self-aligned diffusion break may be characterized by a high aspect ratio due to the small channel length and large diffusion break depth. In addition, in embodiments, only single self-aligned diffusion breaks, and no double diffusion breaks, are utilized in structure 300 while still imparting the necessary stress, thus allowing reduced size while maintaining effectiveness.

Moreover, while the illustrated embodiments contain two single self-aligned diffusion breaks 301, 303 on opposing sides of three gate regions 306 in FIGS. 3A-3H, and two single self-aligned diffusion breaks 301, 303 on opposing sides of a single gate region 306 in FIG. 4, it should be understood that the self-aligned diffusion breaks may be placed with any number of gate regions 306 between a pair of diffusion breaks. For example, one gate region 306 may be disposed between a pair of diffusion breaks, such as two gate regions, three gate regions, such as four gate regions, such as 5 gate regions, such as 6 gate regions, such as 7 gate regions, or more, depending on the desired stress for the channel regions 316 in structure 300. For example the number of channel regions 304 disposed between opposing self-aligned diffusion breaks 312 may be selected to maintain a channel stress of greater than or about 350 MPA, such as greater than or about 400 MPa, greater than or about 450 MPa, greater than or about 500 MPa, greater than or about 550 MPa, such as greater than or about 650 MPa, such as greater than or about 750 MPa, such as greater than or about 850 MPa, such as greater than or about 950 MPa, such as greater than or about 1000 MPa, or more, or any ranges or values therebetween.

As noted above, in embodiments, the stress imparted by the compressive stressed material, which may vastly improve mobility and drive current. Moreover, in embodiments where it is desired, a tensile stressed first fill material may also improve mobility and drive current in a n-MOS region. Thus, in addition to the improvements discussed above, the increased stress in the channel region may increase the mobility of charge carriers in the channel, which also increases the drive current through the n-MOS channel region. In embodiments, the increased stress created in the channel region by embodiments of the present technology may increase the drive current through a transistor channel by greater than or about 1%, such as greater than or about 5%, greater than or about 10%, greater than or about 15%, greater than or about 20%, greater than or about 25%, greater than or about 30%, greater than or about 35%, greater than or about 40%, greater than or about 45%, greater than or about 50%, greater than or about 55%, or greater, or any ranges or values therebetween, in a n-MOS region, a p-MOS region, or both a n-MOS and a p-MOS region. An increase in drive current and hole mobility through the channel region may increase transistor performance in a number of respects including, but not limited to, increased switching speed and/or reduced power consumption.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a dielectric material” includes a plurality of such dielectric materials, and reference to “the gate region” includes reference to one or more gate regions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor device, comprising:
a substrate;
a source region;
a drain region;
a channel region comprising at least one channel located between the source and the drain;
a first gate region comprising a first self-aligned single diffusion break in a n-MOS region, wherein the first self-aligned single diffusion break comprises a first liner and a first fill material; and
a second gate region comprising a second self-aligned single diffusion break in a p-MOS region, wherein the second self-aligned single diffusion break comprises a compressive stressed fill material, and wherein compressive stressed fill material is characterized by a compressive stress of greater than or about 350 MPa.

2. The semiconductor device of claim 1, where the first fill material is a neutral stressed material or a tensile stressed material.

3. The semiconductor device of claim 2, wherein the first fill material, the compressive stressed fill material, or both the first fill material and the compressive stressed fill material comprises a dielectric fill material.

4. The semiconductor device of claim 3, wherein the first fill material and the compressive stressed fill material both comprise dielectric fill materials, wherein the first fill material is different from the compressive stressed fill material.

5. The semiconductor device of claim 3, wherein the dielectric fill material comprises silicon nitride, a silicon oxynitride, silicon dioxide, or a combination thereof.

6. The semiconductor device of claim 1, wherein the second self-aligned single diffusion break comprises a second liner.

7. The semiconductor device of claim 6, wherein the first liner, the second liner, or both the first liner and the second liner comprise a dielectric liner material.

8. The semiconductor device of claim 7, wherein the dielectric liner material comprises silicon nitride, a silicon oxynitride, silicon dioxide, or a combination thereof.

9. The semiconductor device of claim 7, wherein the dielectric liner material of the first liner has an etch rate that is different than an etch rate of the first fill material.

10. The semiconductor device of claim 7, wherein the dielectric liner material of the second liner is selected from a same material or a different material from the compressive stressed fill material.

11. The semiconductor device of claim 7, wherein the second liner comprises silicon nitride, silicon dioxide, or a combination thereof, and the compressive stressed fill material comprises silicon dioxide, silicon nitride, or a combination thereof.

12. The semiconductor device of claim 11, wherein the first fill material comprises silicon nitride, silicon dioxide, or a combination thereof, wherein the compressive stressed fill material is different than the first fill material.

13. The semiconductor device of claim 1, wherein the semiconductor device is a nanosheet field-effect transistor or a complementary field-effect transistor and/or wherein the semiconductor device is a gate-all-around complementary metal-oxide-semiconductor.

14. A semiconductor processing system, comprising:
a first processing chamber;
a second processing chamber;
a third processing chamber; and
a system controller configured to
pattern a substrate in the first processing chamber,
etch a first shallow trench isolation in a first gate region and a second shallow trench isolation in a second gate region of a semiconductor device, wherein the first gate region is a n-MOS region and the second gate region is a p-MOS region, in the second processing chamber,
line the first shallow trench isolation and the second shallow trench isolation with a dielectric liner, fill the first shallow trench isolation and second shallow trench isolation with a neutral stressed material or a tensile stressed material, remove the neutral stressed material or tensile stressed material from the first shallow trench isolation, and fill the first shallow trench isolation with a compressive stressed material, in the third processing chamber.

15. A method of forming a semiconductor device, comprising:
etching a first shallow trench isolation in a first gate region and a second shallow trench isolation in a second gate region of the semiconductor device, wherein the first gate region is a n-MOS region and the second gate region is a p-MOS region, wherein the semiconductor device contains a substrate, a source region, a drain region, a channel region containing at least one channel located between the source and the drain;
lining the first shallow trench isolation and the second shallow trench isolation with a liner;
filling the lined first shallow trench isolation and second shallow trench isolation with a neutral stressed or tensile stressed material;
etching the neutral stressed material or tensile stressed material from the second shallow trench isolation; and
filling the etched second shallow trench isolation with a compressive stressed material.

16. The method of claim 15, wherein no polishing step is conducted between filling the lined first shallow trench isolation with the neutral stressed or tensile stressed material and filling the etched second shallow trench isolation with the compressive stressed material.

17. The method of claim 15, wherein etching the neutral stressed material or tensile stressed material is a wet etching or a dry etching process.

18. The method of claim 17, wherein the liner comprises a dielectric liner material having an etch rate that is different than an etch rate of the neutral stressed material or tensile stressed material.

19. The method of claim 18, wherein the liner comprises silicon nitride, a silicon oxynitride, silicon dioxide, or a combination thereof.

20. The method of claim 19, wherein the compressive stressed material comprises silicon nitride, and wherein the neutral stressed or tensile stressed material comprises silicon nitride or silicon dioxide.
